(19) United States
(12) Patent Application Publication
(10) Pub. No.: US 2025/0323131 A1
(43) Pub. Date: Oct. 16, 2025

(54) SEMICONDUCTOR PACKAGE

(71) Applicant: Samsung Electronics Co., Ltd., Suwon-si (KR)

(72) Inventors: Jusuk Kang, Suwon-si (KR); Jongho Park, Suwon-si (KR); Chanwook Park, Suwon-si (KR); Hyun Yang, Suwon-si (KR); Jaemok Jung, Suwon-si (KR); Taeoh Ha, Suwon-si (KR)

(21) Appl. No.: 18/889,839

(22) Filed: Sep. 19, 2024

(30) Foreign Application Priority Data
Apr. 11, 2024 (KR) 10-2024-0048509

(51) Int. Cl. H01L 23/498; H01L 23/00; H01L 23/31; H01L 25/10

(52) U.S. Cl. CPC H01L 23/49816; H01L 23/49866; H01L 24/24; H01L 25/105; H01L 23/3107; H01L 24/16; H01L 24/32; H01L 24/73; H01L 2224/16227; H01L 2224/32225; H01L 2224/73204; H01L 2225/1041

(57) ABSTRACT

A semiconductor package includes a front redistribution structure that includes a front pad, external connection bumps on the first redistribution structure, a semiconductor chip on the first redistribution structure, an encapsulant that is on the front redistribution structure and on a portion of the semiconductor chip, a rear redistribution structure that includes rear redistribution layers, and an interconnection structure that extends into the encapsulant and is electrically connecting the front pad and the rear redistribution layers, where the interconnection structure overlaps at least a portion of an upper surface of the front pad in a first direction that is perpendicular to the first surface of the front redistribution structure and overlaps at least a portion of a side surface of the front pad in a second direction that is parallel to the first surface of the front redistribution structure.

### CROSS-REFERENCE TO RELATED APPLICATION(S)

This application claims the benefit under 35 USC 119(a) of Korean Patent Application No. 10-2024-0048509 filed on Apr. 11, 2024 in the Korean Intellectual Property Office, the entire disclosure of which is incorporated herein by reference for all purposes.

### TECHNICAL FIELD

The present disclosure relates to semiconductor packages.

### BACKGROUND

As electronic devices become lighter and have been implemented with higher levels of performance, there is a demand for development of smaller and higher performing semiconductor chips. To improve the reliability of high-performance semiconductor chips, improving heat dissipation characteristics of semiconductor packages may be desirable.

### SUMMARY

Example embodiments provide a semiconductor package having improved electrical characteristics and reliability.

According to example embodiments, a semiconductor package includes a front redistribution structure that includes a front insulating layer, front redistribution layers in the front insulating layer, and a front pad on the front insulating layer, external connection bumps that are on a first surface of the front redistribution structure and electrically connected to the front redistribution layers, a semiconductor chip on a second surface of the front redistribution structure that is opposite to the first surface of the front redistribution structure, an encapsulant that is on the front redistribution structure and on a portion of the semiconductor chip, a rear redistribution structure that includes a rear insulating layer on the encapsulant and rear redistribution layers in the rear insulating layer, and an interconnection structure that extends into the encapsulant and is electrically connecting the front pad and the rear redistribution layers, where the interconnection structure overlaps at least a portion of an upper surface of the front pad in a first direction that is perpendicular to the first surface of the front redistribution structure and overlaps at least a portion of a side surface of the front pad in a second direction that is parallel to the first surface of the front redistribution structure.

According to example embodiments, a semiconductor package includes a front redistribution structure that includes a front insulating layer and front redistribution layers in the front insulating layer, a semiconductor chip that is on the front redistribution structure and is electrically connected to the front redistribution layers, a front pad that is spaced apart from the semiconductor chip in a first direction that is parallel to a lower surface of the front redistribution structure, is on the front redistribution structure, and is electrically connected to the front redistribution layers, and an interconnection structure on the front pad, where a lower surface of the interconnection structure includes: a first lower surface portion in contact with an upper surface of the front pad, a second lower surface portion having a level relative to the lower surface of the front redistribution structure that is lower than a level of the first lower surface portion relative to the lower surface of the front redistribution structure, and an inner side surface connecting the first lower surface portion and the second lower surface portion.

According to example embodiments, a semiconductor package includes a front redistribution structure that includes a front insulating layer, front redistribution layers in the front insulating layer, and a front pad on the front insulating layer, a semiconductor chip on a first surface of the front redistribution structure, external connection bumps that is on a second surface of the front redistribution structure and is electrically connected to the front redistribution layers, where the second surface of the front redistribution structure is opposite to the first surface of the front redistribution structure, an encapsulant that is on the front redistribution structure and a portion of the semiconductor chip, a rear redistribution structure that includes a rear insulating layer on the encapsulant and rear redistribution layers in the rear insulating layer, and an interconnection structure that extends into the encapsulant and is electrically connected to the front pad and the rear redistribution layers, where the front pad is in the interconnection structure and is spaced apart from the encapsulant in a first direction that is parallel to the first surface of the front redistribution structure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a schematic cross-sectional view illustrating a semiconductor package according to example embodiments;

FIG. 1B is a schematic enlarged view illustrating a portion of a semiconductor package according to example embodiments;

FIG. 1C is a schematic enlarged view illustrating a portion of a semiconductor package according to example embodiments;

FIGS. 2, 3, 4, 5, and 6 are schematic enlarged views illustrating partial areas of a semiconductor package according to example embodiments;

FIG. 7 is a schematic cross-sectional view illustrating a semiconductor package according to example embodiments;

FIG. 8 is a schematic cross-sectional view illustrating a semiconductor package according to example embodiments;

FIGS. 9A, 14A, 15A, 16, 17, 18, 19, and 20 are diagrams illustrating a process sequence to illustrate a method of manufacturing a semiconductor package according to example embodiments; and

FIGS. 9B, 10, 11, 12, 13, 14B, and 15B are enlarged views illustrating a process sequence to illustrate a method of manufacturing a semiconductor package according to example embodiments.

### DETAILED DESCRIPTION

Hereinafter, example embodiments will be described with reference to the accompanying drawings. Below, terms such as ‘upper,’ ‘top,’ ‘upper surface,’ ‘bottom,’ ‘lower,’ ‘lower surface,’ ‘side,’ and the like, may be understood as referring to the drawings, except where otherwise indicated by reference numerals.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device.

Hereinafter, example embodiments will be explained in detail with reference to the accompanying drawings.

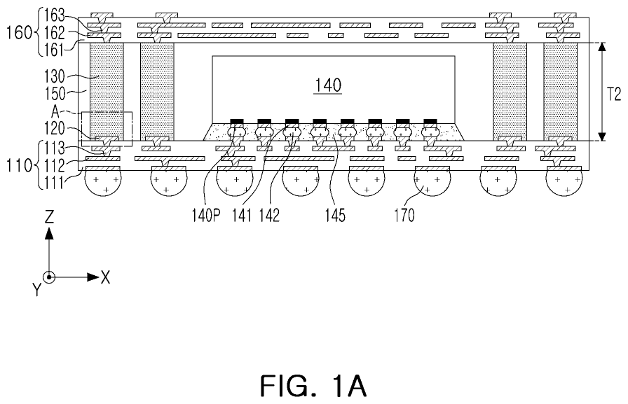

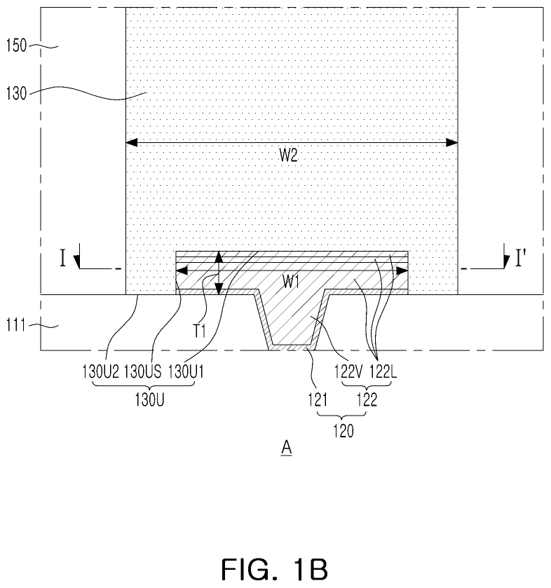

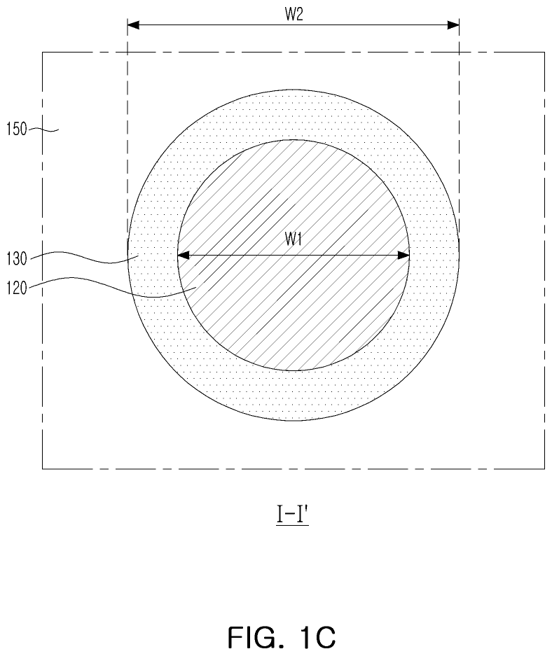

FIG. 1A is a schematic cross-sectional view illustrating a semiconductor package 10 according to example embodiments.

FIG. 1B is a schematic enlarged view illustrating a portion of a semiconductor package according to example embodiments. FIG. 1B illustrates an enlarged view of area ‘A’ in FIG. 1A.

FIG. 1C is a schematic enlarged view illustrating a portion of a semiconductor package according to example embodiments. FIG. 1C schematically illustrates a cross section cut along the cutting line I-I′ in FIG. 1B.

Referring to FIGS. 1A to 1C, a semiconductor package 10 according to example embodiments may include a front redistribution structure 110, a front pad 120, an interconnection structure 130, a semiconductor chip 140, an encapsulant 150, a rear redistribution structure 160, and external connection bumps 170.

The front redistribution structure 110 may include a front insulating layer 111, front redistribution layers 112, and front redistribution vias 113. Depending on the explanation method, the front redistribution structure 110 may be described as including the front pads 120, but is described as a separate configuration. The front redistribution structure 110 may be a support substrate on which the semiconductor chip 140 is mounted.

The front insulating layer 111 may include an insulating resin. The insulating resin may include a thermosetting resin such as epoxy resin, a thermoplastic resin such as polyimide, or a resin that is impregnated with inorganic fillers or the like, for example, prepreg, Ajinomoto Build-up Film (ABF), FR-4, or Bismaleimide-Triazine (BT). For example, the front insulating layer 111 may include a photosensitive resin such as Photo-Imageable Dielectric (PID). The front insulating layer 111 may include a plurality of insulating layers (not illustrated) stacked in the vertical direction (Z-axis direction). Depending on the process, the boundaries between a plurality of insulating layers (not illustrated) may be unclear.

The front redistribution layers 112 are disposed on or within the front insulating layer 111 and may redistribute the connection terminal 140P of the semiconductor chip 140. The front redistribution layers 112 may include a metal such as, for example, copper (Cu), aluminum (Al), silver (Ag), tin (Sn), gold (Au), nickel (Ni), lead (Pb), titanium (Ti), or alloys thereof. The front redistribution layers 112 may perform various functions depending on the design. For example, the front redistribution layers 112 may include a ground (GND) pattern, a power (PWR) pattern, and a signal (S) pattern. In this case, the signal (S) pattern may be defined as a transmission path for various signals, for example, data signals and the like, excluding the ground (GND) pattern, power (PWR) pattern, or the like. The front redistribution layers 112 may include more or fewer redistribution layers than illustrated in the drawing. The front redistribution layers 112 disposed on the front insulating layer 111 may be electrically connected to the connection terminals 140P of the semiconductor chip 140. The front pads 120 disposed on the upper surface of the front insulating layer 111 may be electrically connected to the interconnection structures 130. To distinguish between the front redistribution layers 112 connected to the connection terminals 140P of the semiconductor chip 140 and the front pad 120 connected to the interconnection structure 130, the front pad 120 is described as a separate configuration.

The front redistribution vias 113 may extend vertically within the front insulating layer 111 and be electrically connected to the front redistribution layers 112. For example, the front redistribution vias 113 may interconnect the front redistribution layers 112 provided at different levels relative to a lower surface of the front insulating layer 111. The front redistribution vias 113 may include signal vias, ground vias, and power vias. The front redistribution vias 113 may include a metal material such as, for example, copper (Cu), aluminum (Al), silver (Ag), tin (Sn), gold (Au), nickel (Ni), lead (Pb), titanium (Ti), or alloys thereof. The front redistribution vias 113 may be filled vias in which the inside of the via hole is at least partially filled with a metal material, or conformal vias in which the metal material extends along the inner wall of the via hole.

The front pads 120 are in contact with the interconnection structure 130 on the front insulating layer 111, and may electrically connect the interconnection structure 130 and the front redistribution layers 112 in the front insulating layer 111. The front pads 120 may be disposed on the front redistribution structure 110 to be spaced apart from the semiconductor chip 140 in a horizontal direction (for example, the X-direction or Y-direction). The front pads 120 may each include a pad seed layer 121 and a pad conductive layer 122. The pad seed layer 121 may conformally cover or overlap the front insulating layer 111 in a vertical direction (e.g., Z-direction), and the pad conductive layer 122 may be disposed on the pad seed layer 121. The surface of the pad seed layer 121 in contact with the front insulating layer 111 may be defined as the lower surface of the pad seed layer 121, and the surface opposite to the lower surface of the pad seed layer 121 may be defined as the upper surface of the pad seed layer 121. For example, the lower surface of the pad seed layer 121 may be in contact with the front insulating layer 111, and the pad conductive layer 122 may be disposed on the upper surface of the pad seed layer 121. The pad conductive layer 122 may contact at least a portion of the upper surface of the pad seed layer 121. In example embodiments, the pad conductive layer 122 may contact the entire upper surface of the pad seed layer 121. On the upper surface of the front insulating layer 111, the surface connecting the upper surface and the lower surface of the pad seed layer 121 may be defined as the side surface of the pad seed layer 121. In example embodiments, the side surface of the pad seed layer 121 may form a portion of the side of the front pad 120. The pad conductive layer 122 may include a layer portion 122L on the front insulating layer 111 and a via portion 122V extending from the lower surface of the layer portion 122L into the front insulating layer 111. The upper and side surfaces of the front pad 120 may be defined as the upper and side surfaces of the pad conductive layer 122. The upper and side surfaces of the front pad 120 may be in contact with the interconnection structure 130. The front pad 120 may be buried within the interconnection structure 130 and may be spaced apart from the encapsulant 150. Referring to FIG. 1C, the upper surface of the front pad 120 may have a circular shape, but is not limited thereto. For example, the upper surface of the front pad 120 may have an oval shape or a polygonal shape. The pad conductive layer 122 may include a plurality of conductive layers. The front pads 120 may include a metal such as, for example, copper (Cu), aluminum (Al), silver (Ag), tin (Sn), gold (Au), nickel (Ni), lead (Pb), titanium (Ti), or alloys thereof. In example embodiments, the pad seed layer 121 may include titanium (Ti) or titanium nitride (TiN), and the pad conductive layer 122 may include at least one of copper (Cu), nickel (Ni), and gold (Au). In example embodiments, the pad conductive layer 122 including a plurality of conductive layers may sequentially include a copper (Cu) layer, a nickel (Ni) layer, and a gold (Au) layer from the bottom. If a maximum width of the front pad 120 in the horizontal direction (for example, X-direction or Y-direction) is defined as the first width W1, the first width W1 may be, for example, 50 μm to 300 μm. In example embodiments, the first width W1 may be 80 μm to 250 μm, 100 μm to 200 μm, or 110 μm to 150 μm, but is not limited thereto. Since the front pad 120 has a structure buried in the interconnection structure 130, the first width W1 may be formed to be smaller depending on example embodiments. For example, the first width W1 may be formed to be 50 μm or less. In example embodiments, the first width W1 may be 0.5 μm to 5 μm, or 0.01 μm to 0.5 μm. The first width W1 may be variously modified within a range that is equal to or smaller than the second width W2 of the interconnection structure 130. If the thickness of the front pad 120 in the vertical direction (for example, Z-direction) is defined as the first thickness T1, the first thickness T1 may be variously modified in a range smaller than the first width W1.

The interconnection structure 130 may penetrate or extend into the encapsulant 150 to electrically connect the front redistribution layers 112 and the rear redistribution layers 152. The interconnection structure 130 may extend in a vertical direction (for example, Z-direction) within the encapsulant 150. The upper surface of the interconnection structure 130 is exposed from the encapsulant 150 and may be substantially coplanar surface with the upper surface of the encapsulant 150. The interconnection structure 130 may cover or overlap at least a portion of the upper and side surfaces of the front pad 120 in a horizontal direction and a vertical direction (e.g., X-direction and Z-direction). The interconnection structure 130 is in direct contact with the upper and side surfaces of the front pad 120, and the front pad 120 may be spaced apart from the encapsulant 150. The interconnection structure 130 may be shaped to at least partially surround the upper and side surfaces of the front pad 120 in the horizontal direction (e.g., X-direction), and the lower surface 130U of the interconnection structure 130 may include a first lower surface portion 130U1 in contact with the upper surface of the front pad 120, a second lower surface portion 130U2 located at a lower level relative to the lower surface of the front insulating layer 111 than a level of the first lower surface portion 130U1 relative to the lower surface of the front insulating layer 111, and an inner side surface 130US connecting the first lower surface portion 130U1 and the second lower surface portion 130U2. The first lower surface portion 130U1 may cover or overlap at least a portion of the upper surface of the front pad 120 in the vertical direction (e.g., the Z-direction). In example embodiments, the first lower surface portion 130U1 may cover or overlap the entire upper surface of the front pad 120 in the vertical direction (e.g., the Z-direction). The inner side surface 130US may be formed along the side of the front pad 120 and may cover or overlap at least a portion of the side of the front pad 120 in the horizontal direction (e.g., the X-direction). In example embodiments, the inner side surface 130US may cover or overlap the entire side of the front pad 120 in the horizontal direction (e.g., the X-direction). For example, the interconnection structure 130 may at least partially surround the side of the front pad 120. The second lower surface portion 130U2 may at least partially surround the first lower surface portion 130U1. The second lower surface portion 130U2 may contact the upper surface of the front insulating layer 111. For example, the interconnection structure 130 may contact the front insulating layer 111. The second lower surface portion 130U2 is located at the lowest level of the interconnection structure 130 relative to the lower surface of the front insulating layer 111 and may form the lower end of the interconnection structure 130. In this case, the lower end may refer to a part located at the lowest level of a certain configuration relative to the lower surface of the front insulating layer 111. Conversely, the upper end of a certain configuration may refer to a portion located at the highest level of the configuration relative to the lower surface of the front insulating layer 111. In example embodiments, the upper end of the interconnection structure 130 may be located at the same level or higher than the upper end of the semiconductor chip 140. The level difference between the first lower surface portion 130U1 and the second lower surface portion 130U2 may be equal to the first thickness T1 of the front pad 120. The lower end of the interconnection structure 130 may be located at a lower level relative to the lower surface of the front insulating layer 111 than a level of the upper surface of the front pad 120 relative to the lower surface of the front insulating layer 111. For example, the interconnection structure 130 may have a post shape penetrating or extending into the encapsulant 150. Referring to FIG. 1C, the cross-section of the interconnection structure 130 may have a circular shape, but is not limited thereto. For example, the upper surface of the front pad 120 may have an oval shape or a polygonal shape. The interconnection structure 130 may include a metal material such as copper (Cu). The interconnection structure 130 may include a metal such as, for example, copper (Cu), aluminum (Al), silver (Ag), tin (Sn), gold (Au), nickel (Ni), lead (Pb), titanium (Ti), or alloys thereof. If the maximum width of the interconnection structure 130 in the horizontal direction (for example, X-direction or Y-direction) is defined as the second width W2, the second width W2 may be equal to or greater than the first width W1 of the front pad 120. The second width W2 may be, for example, 5 μm to 500 μm. In example embodiments, the second width W2 may be 100 μm to 400 μm, 120 μm to 300 μm, 150 μm to 200 μm, or 5 μm to 50 μm. The range of the second width W2 is not limited thereto, and may be varied in various manners within a range equal to or greater than the first width W1 of the front pad 120. For example, in the direction horizontal to the upper surface of the front insulating layer 111 (for example, X-direction or Y-direction), the maximum width W1 of the front pad 120 may be smaller than the maximum width W2 of the interconnection structure. The thickness of the interconnection structure 130 in the vertical direction (for example, Z-direction) may be defined as the second thickness T2. The second thickness T2 may be the distance between the upper end and the lower end of the interconnection structure 130, or the distance between the upper surface of the interconnection structure 130 and the second lower surface portion 130U2. In example embodiments, the second thickness T2 may be, but is not limited to, 50 μm to 400 μm.

The semiconductor package of the present disclosure may have a shape in which the second width W2 of the interconnection structure 130 has a greater width than the first width W1 of the front pad 120, and the interconnection structure 130 covers or overlaps at least a portion of the upper and side surfaces of the front pad 120. Accordingly, the electrical characteristics of the semiconductor package may be improved and the structural reliability may be strengthened or improved.

The semiconductor chip 140 is disposed on the front redistribution structure 110, and may include a connection terminal 140P electrically connected to the front redistribution layers 112. The semiconductor chip 140 may be referred to as a lower semiconductor chip 140 or a first semiconductor chip 140. The semiconductor chip 140 may include semiconductor wafers formed of semiconductor elements such as silicon and germanium, or compound semiconductors such as silicon carbide (SiC), gallium arsenide (GaAs), indium arsenide (InAs), and indium phosphide (InP), and a semiconductor wafer integrated circuit (IC). The semiconductor chip 140 may be a bare semiconductor chip without separate bumps or interconnection layers, but is not limited thereto and may be a packaged type semiconductor chip. The integrated circuit may be a logic circuit (or ‘logic chip’) such as a central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC), and the like, or may be a memory circuit (or ‘memory chip’) including a volatile memory, such as dynamic RAM (DRAM) and a static RAM (SRAM), and a non-volatile memory such as phase change RAM (PRAM), a magnetic RAM (MRAM), a resistive RAM (RRAM), and a flash memory.

The semiconductor chip 140 may include a connection pillar 141 and a connection solder 142 connecting the connection terminal 140P to the front redistribution layers 112 on the front insulating layer 111. The connection pillar 141 and the connection solder 142 may be disposed between the front redistribution layers 112 on the front insulating layer 111 and the connection terminal 140P. An underfill layer 145 may be disposed between the semiconductor chip 140 and the front redistribution structure 110. The underfill layer 145 includes an insulating resin such as epoxy resin and may physically and electrically protect the connection pillar 141 and the connection solder 142. The underfill layer 145 may have a capillary underfill (CUF) structure, but is not limited thereto. Depending on example embodiments, the underfill layer 145 may have a molded underfill (MUF) structure integrated with the encapsulant 150.

The encapsulant 150 may be on or seal at least a portion of the semiconductor chip 140 on the upper surface of the front redistribution structure 110. The encapsulant 150 may cover or overlap the side and upper surfaces of the semiconductor chip 140 in a horizontal direction and a vertical direction (e.g., X-direction and Z-direction). The encapsulant 150 may include, for example, a thermosetting resin such as an epoxy resin, a thermoplastic resin such as polyimide, or prepreg, ABF, FR-4, BT or epoxy molding compound (EMC) in which these resins are impregnated with an inorganic fillers or the like. For example, the encapsulant 150 may include EMC.

The rear redistribution structure 160 is disposed on the semiconductor chip 140 and the encapsulant 150, and may include a rear insulating layer 161, rear redistribution layers 162, and rear redistribution vias 163.

The rear insulating layer 161 may include insulating resin. The insulating resin may include a thermosetting resin such as an epoxy resin, a thermoplastic resin such as polyimide, or a resin impregnated with an inorganic filler or the like, such as prepreg, ABF, FR-4, BT, or PID. The rear insulating layer 161 may include a plurality of layers stacked in the vertical direction (Z-axis direction). Depending on the process, the boundaries between multiple layers may be unclear.

The rear redistribution layers 162 are disposed on or within the rear insulating layer 161 and may redistribute the interconnection structure 130. The rear redistribution layers 162 may include a metal material such as, for example, copper (Cu), aluminum (Al), silver (Ag), tin (Sn), gold (Au), nickel (Ni), lead (Pb), titanium (Ti), or alloys thereof. The rear redistribution layers 162 may include more or less redistribution layers than illustrated in the drawing. The rear redistribution layers 162 on the rear insulating layer 161 may be physically and electrically connected to external devices. A barrier layer (not illustrated) may be disposed on the surface of the rear redistribution layers 162 on the rear insulating layer 161.

The rear redistribution vias 163 may penetrate or extend into the rear insulating layer 161 and be electrically connected to the rear redistribution layers 162. For example, the rear redistribution vias 163 may interconnect rear redistribution layers 162 at different levels relative to the lower surface of the front insulating layer 111. The rear redistribution via 163 may be a filled via in which the inside of the via hole is at least partially filled with a metal material, or a conformal via in which a metal material extends along the inner wall of the via hole.

The external connection bumps 170 may be disposed below the front redistribution structure 110. The external connection bumps 170 may be electrically connected to the semiconductor chip 140 and the interconnection structure 130 through the front redistribution layers 112. The semiconductor package 10 may be connected to an external device such as a module substrate or system board through external connection bumps 170. For example, the external connection bumps 170 may include a low melting point metal, for example, tin (Sn) or an alloy containing tin (Sn). Depending on example embodiments, the external connection bumps 170 may have a shape that is a combination of a pillar (or underbump metal) and a ball. The pillar may include copper (Cu) or an alloy of copper (Cu), and the ball may include a solder ball. Depending on example embodiments, the front insulating layer 111 may include a resist layer that protects the external connection bumps 170 from external physical and chemical damage.

In the following description, descriptions that overlap with those described with reference to FIGS. 1A to 1C will be omitted. Additionally, overlapping descriptions in respective embodiments are omitted.

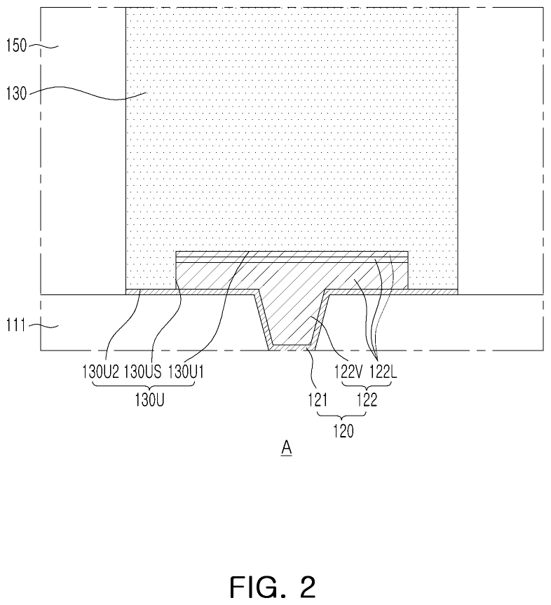

FIGS. 2 to 6 are schematic enlarged views illustrating partial areas of a semiconductor package according to example embodiments. FIGS. 2 to 6 illustrate variations of the enlarged view of area ‘A’ in FIG. 1A.

Referring to FIG. 2, unlike FIG. 1B, the pad seed layer 121 of the front pad 120 may be extended to be disposed not only between the pad conductive layer 122 and the front insulating layer 111, but also between the interconnection structure 130 and the front insulating layer 111. Accordingly, the pad seed layer 121 may contact the interconnection structure 130. The pad conductive layer 122 may contact a portion of the upper surface of the pad seed layer 121, and the interconnection structure 130 may contact the remaining portion of the upper surface of the pad seed layer 121. The interconnection structure 130 may be spaced apart from the front insulating layer 111 without contacting the front insulating layer 111 by the pad seed layer 121. For example, the second lower surface portion 130U2 of the interconnection structure 130 may contact the upper surface of the pad seed layer 121 without contacting the front insulating layer 111. The second lower surface portion 130U2 of the interconnection structure 130 may be located at a level relative to the lower surface of the front insulating layer 111 that is lower than a level the upper surface of the front pad 120 relative to the lower surface of the front insulating layer 111 and higher than a level of the upper surface of the front insulating layer 111 relative to the lower surface of the front insulating layer 111.

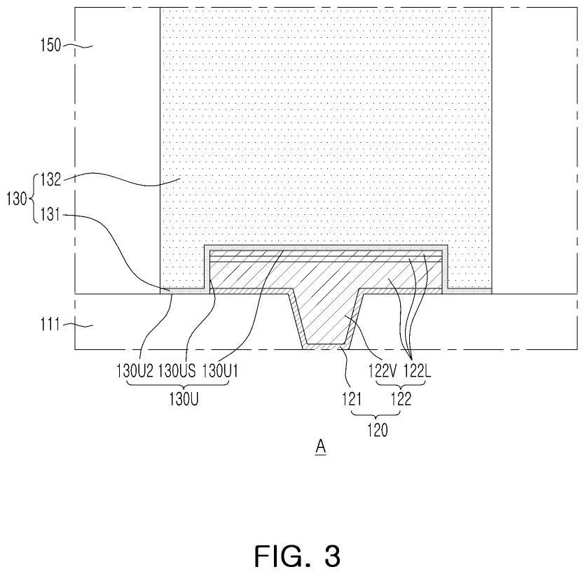

Referring to FIG. 3, the interconnection structure 130 may include an interconnection seed layer 131 and an interconnection post 132. The interconnection seed layer 131 may form the lower surface 130U of the interconnection structure 130 and may contact the upper surface and side surface of the front pad 120. The interconnection seed layer 131 may be in contact with the front insulating layer 111. The interconnection seed layer 131 may surround the upper and side surfaces of the front pad 120. The thickness of the interconnection seed layer 131 may be substantially the same as the thickness of the pad seed layer 121, but is not limited thereto. For example, the thickness of the interconnection seed layer 131 may be greater or smaller than the thickness of the pad seed layer 121 depending on example embodiments. The interconnection post 132 may be disposed on the interconnection seed layer 131 and may penetrate or extend into the encapsulant 150. In example embodiments, the interconnection seed layer 131 may include titanium (Ti) or titanium nitride (TiN), and the interconnection post 132 may include copper (Cu).

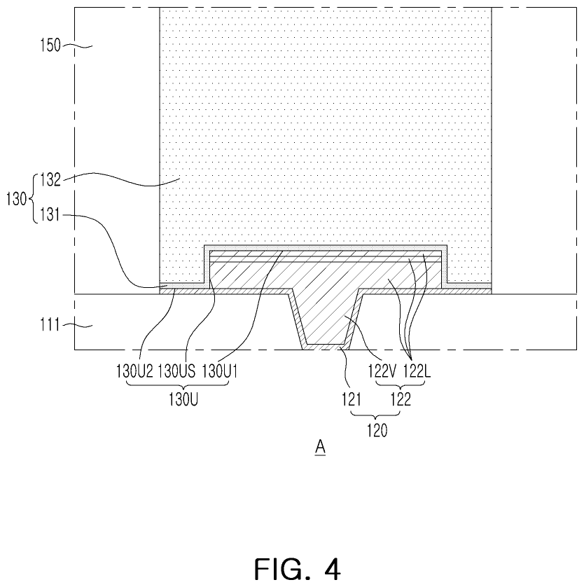

Referring to FIG. 4, unlike FIG. 3, the pad seed layer 121 of the front pad 120 may extend to be disposed not only between the pad conductive layer 122 and the front insulating layer 111, but also between the interconnection seed layer 131 and the front insulating layer 111. The pad seed layer 121 of the front pad 120 may contact the interconnection seed layer 131 constituting the second lower surface portion 130U2 of the interconnection structure 130. The pad conductive layer 122 may cover or overlap a portion of the upper surface of the pad seed layer 121 in the vertical direction (e.g., Z-direction), and the interconnection seed layer 131 may cover or overlap the remaining portion of the upper surface of the pad seed layer 121 in the vertical direction (e.g., Z-direction). The pad seed layer 121 allows the interconnection seed layer 131 to be spaced apart from the front insulating layer 111 without contacting the front insulating layer 111. The portion constituting the second lower surface portion 130U2 of the interconnection seed layer 131 may contact the upper surface of the pad seed layer 121 without contacting the front insulating layer 111.

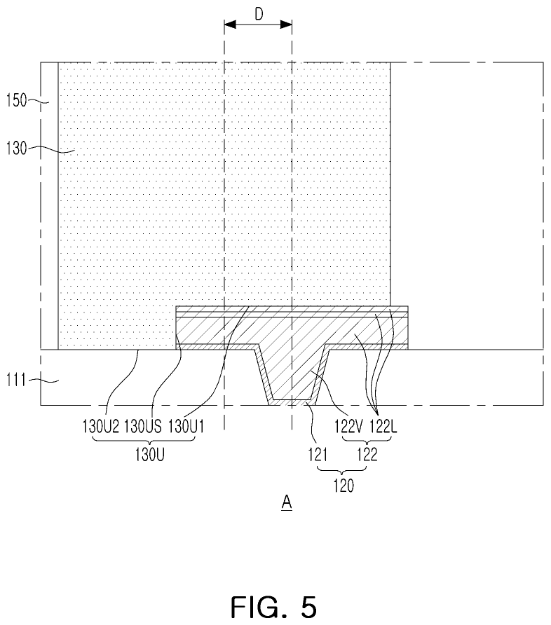

Referring to FIG. 5, unlike FIG. 1B, a center axis difference D may occur between the center axis of the interconnection structure 130 and the center axis of the front pad 120, which may be due to misalignment occurring during the formation of the interconnection structure 130 in example embodiments. Unlike FIG. 1B, the first lower surface portion 130U1 of the interconnection structure 130 may cover or overlap a portion of the front pad 120 in the vertical direction (e.g., Z-direction), and the second lower surface portion 130U2 of the interconnection structure 130 may not surround the first lower surface portion 130U1. The inner side surface 130US of the interconnection structure 130 may cover or overlap a portion of the side surface of the front pad 120 in the horizontal direction (e.g., X-direction).

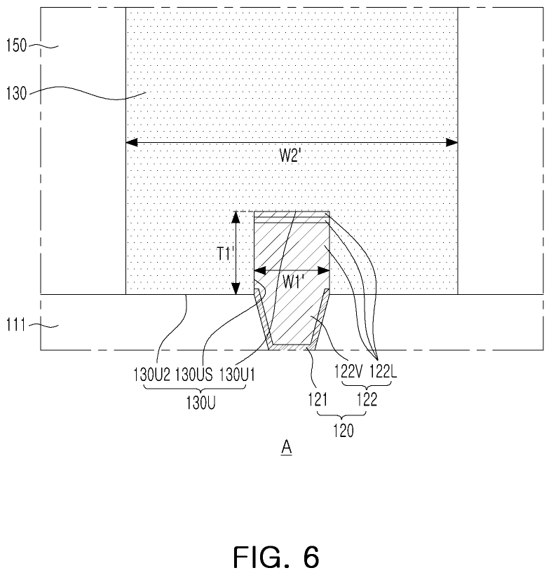

Referring to FIG. 6, in example embodiments, the first width W1′ of the front pad 120 may be smaller than the first thickness T1′. The first width W1′ of the front pad 120 may be variously modified within a range smaller than the second width W2′ of the interconnection structure 130, and depending on example embodiments, the front pad 120 may have a first width W1′ in the horizontal direction smaller than a first thickness T1′ in the vertical direction. Depending on example embodiments, the first thickness T1′ of the front pad 120 may be modified in various manners within a range smaller than the second thickness T2′ of the interconnection structure 130 (see FIG. 1A).

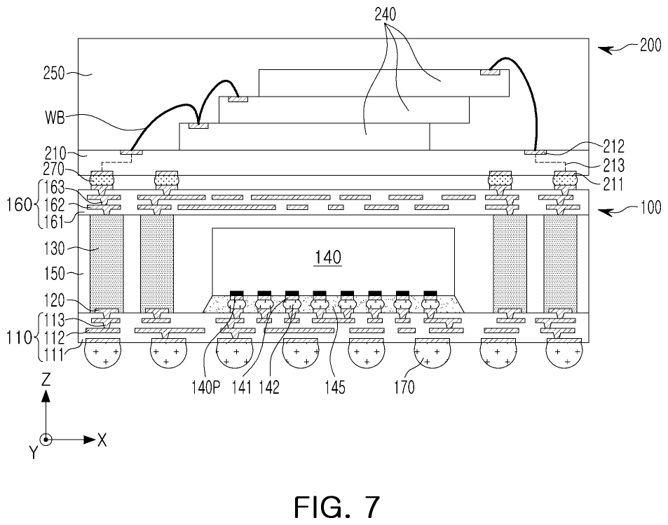

FIG. 7 is a schematic cross-sectional view illustrating a semiconductor package according to example embodiments.

Referring to FIG. 7, a semiconductor package 10A may include a lower package 100 and an upper package 200. The lower package 100 may have the same or similar characteristics as the semiconductor package 100 of FIG. 1, and modifications of FIGS. 2 to 6 may be applied. Depending on the description method, the lower package 100 may be referred to as the first package 100, and the upper package 200 may be referred to as the second package 200.

The upper package 200 may include an upper package substrate 210, an upper semiconductor chip 240, and an upper encapsulant 250. The upper package substrate 210 may include a lower pad 211 and an upper pad 212 on lower and upper surfaces thereof, respectively, which may be electrically connected to components external to the upper package substrate 210. Additionally, the upper package substrate 210 may include a redistribution circuit 213 that electrically connects the lower pad 211 and the upper pad 212.

The upper semiconductor chip 240 may be mounted on the upper package substrate 210 using a wire bonding or flip chip bonding method. For example, the plurality of upper semiconductor chips 240 may be stacked in a vertical direction on the upper package substrate 210 and electrically connected to the upper pad 212 of the upper package substrate 210 by a bonding wire WB. In an example, the upper semiconductor chip 240 may include a memory chip, and the semiconductor chip 140 may include an AP chip.

The upper encapsulant 250 may include the same or similar material as the encapsulant 150 of the lower package 100. The upper package 200 may be physically and electrically connected to the lower package 100 by a conductive bump 270. The conductive bump 270 may be electrically connected to the redistribution circuit 213 inside the upper package substrate 210 through the lower pad 211 of the upper package substrate 210. The conductive bump 270 may include a low melting point metal, for example, tin (Sn) or an alloy containing tin (Sn).

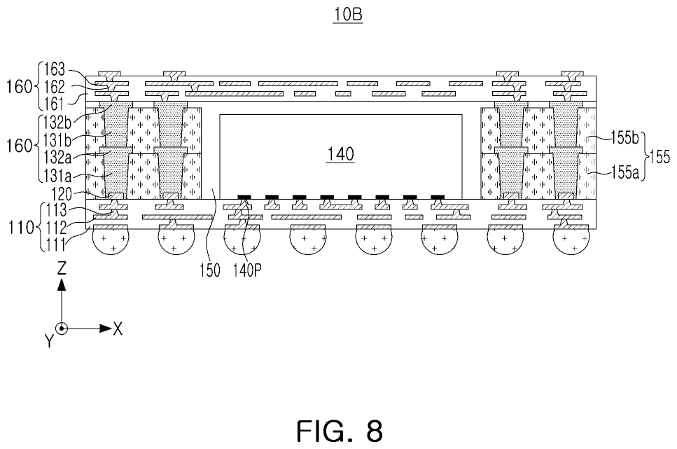

FIG. 8 is a schematic cross-sectional view illustrating a semiconductor package according to example embodiments.

Referring to FIG. 8, in a semiconductor package 10B, the interconnection structure 130 may be disposed around the semiconductor chip 140 and may include first and second intermediate interconnection vias 131a and 131b and first and second intermediate interconnection layers 132a and 132b. The semiconductor package 10B may further include an intermediate insulating layer 155 that covers or overlaps at least a portion of the interconnection structure 130 in the vertical direction (e.g., Z-direction).

The intermediate insulating layer 155 may surround at least a portion of the interconnection structure 130, and the encapsulant 150 may cover or overlap at least a portion of each of the interconnection structure 130 and the intermediate insulating layer 155 in a horizontal direction and the vertical direction (e.g., the X-direction and the Z-direction). The intermediate insulating layer 155 may include a first intermediate insulating layer 155a disposed on the upper surface of the front redistribution structure 110 and a second intermediate insulating layer 155b disposed on the upper surface of the first intermediate insulating layer 155a. The front pad 120 is buried in the lower surface of the first intermediate insulating layer 155a, the first intermediate interconnection layer 132a is disposed on the upper surface of the first intermediate insulating layer 155a, and the second intermediate interconnection layer 132b may be disposed on the upper surface of the second intermediate insulating layer 155b. The first intermediate interconnection via 131a may connect the front pad 120 and the first intermediate interconnection layer 132a by penetrating or extending into the first intermediate insulating layer 155a, and the second intermediate interconnection via 131b may connect the first and second intermediate interconnection layers 132a and 132b by penetrating or extending into the second intermediate insulating layer 155b.

The encapsulant 150 may cover or overlap at least a portion of the intermediate insulating layer 155 in a horizontal direction and the vertical direction (e.g., the X-direction and the Z-direction), and the upper surface of the encapsulant 150 and the upper surface of the second intermediate interconnection layer 132b may be substantially coplanar. Other features of the semiconductor package 10B that are not specifically described here may have the same or similar features as the semiconductor package 10 described with reference to FIG. 1A.

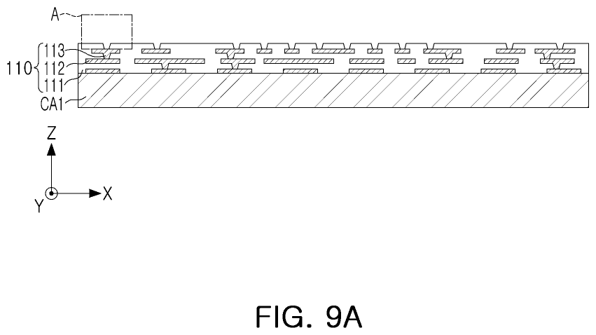

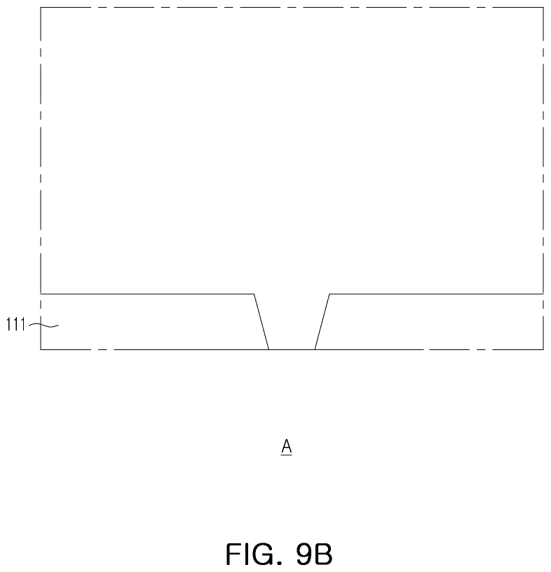

FIGS. 9A, 14A, 15A, and 16 to 20 are diagrams illustrating a process sequence to describe a method of manufacturing a semiconductor package according to example embodiments. These drawings illustrate the method of manufacturing the semiconductor package 10 illustrated in FIG. 1A.

FIGS. 9B, 10 to 13, 14B, and 15B are enlarged views illustrating a process sequence to describe a method of manufacturing a semiconductor package according to example embodiments. These drawings illustrate the area corresponding to area ‘A’ in FIG. 1A and illustrate the manufacturing method for the example embodiment corresponding to FIG. 3.

Processes may be understood as progressing according to the sequential order of drawing numbers, and drawings with the same number may be understood as indicating processes proceeding simultaneously. For example, the processes of FIGS. 9A and 9B may be understood to proceed simultaneously.

Referring to FIGS. 9A and 9B, the front redistribution structure 110 may be formed on a first carrier CA1. For example, the first carrier CA1 may be sequentially coated with a polymer layer containing a curable resin and a metal layer comprising nickel (Ni), titanium (Ti), or the like, on a copper clad laminate (CCL). The front redistribution structure 110 may include a front insulating layer 111, front redistribution layers 112, and front redistribution vias 113. The front insulating layer 111 may be formed by sequentially applying and curing a photoimageable dielectric material, for example, PID. The front redistribution layers 112 and the front redistribution vias 113 may be formed by performing an exposure process and a development process to form a via hole penetrating or extending into the front insulating layer 111 and patterning a metal material on the front insulating layer 111 using a plating process. The via hole formed in the upper surface of the front insulating layer 111 may expose a portion of the front redistribution layers 112 in the front insulating layer 111.

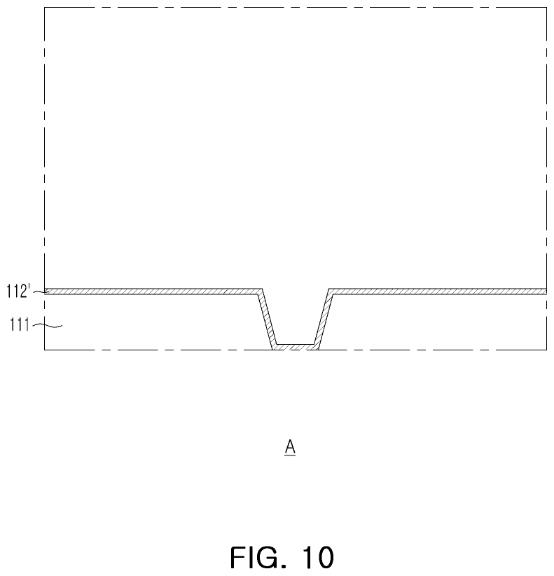

Referring to FIG. 10, a preliminary pad seed layer 121′ may be formed to conformally cover or overlap the upper surface of the front insulating layer 111 in the vertical direction (e.g., Z-direction). The preliminary pad seed layer 121′ may cover or overlap the exposed upper surface of the front redistribution layers 112′ in the vertical direction (e.g., Z-direction) exposed by the via hole. The preliminary pad seed layer 121′ may be formed, for example, by a deposition process such as physical vapor deposition (PVD) or chemical vapor deposition (CVD), and may include titanium (Ti) or titanium nitride (TiN).

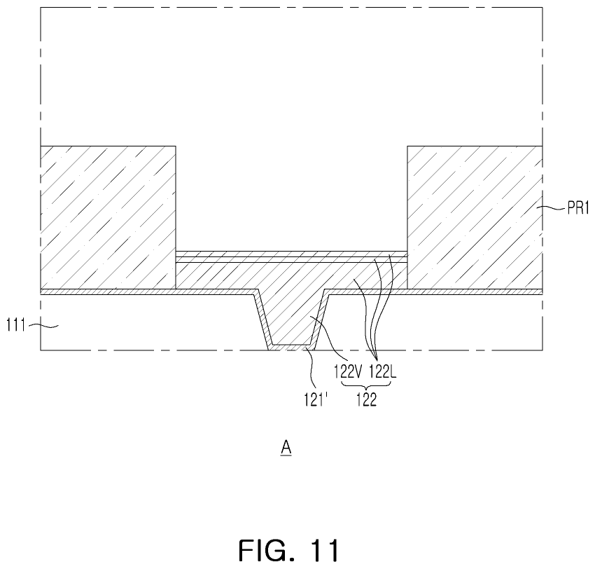

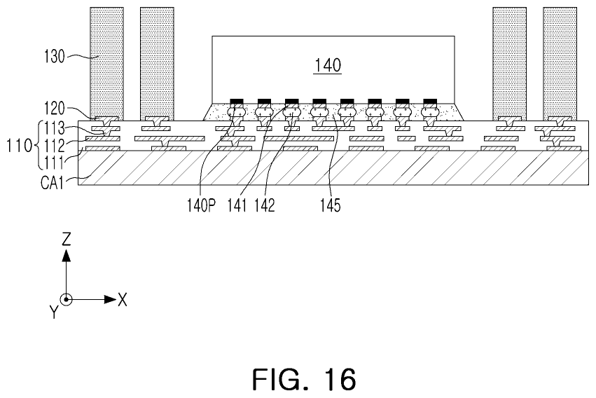

Referring to FIG. 11, a first photoresist pattern PRI may be formed on the preliminary pad seed layer 121′. The first photoresist pattern PRI may expose the pad conductive layer 122 and portions in which the front redistribution layers 112 on the front insulating layer 111 connected to the semiconductor chip 140 in a subsequent process (see FIG. 16) are to be formed, and may cover or overlap the remaining portion of the preliminary pad seed layer 121′ in the vertical direction (e.g., Z-direction). A pad conductive layer 122 may be formed on the preliminary pad seed layer 121′ exposed by the first photoresist pattern PR1. At this time, the front redistribution layers 112 connected to the semiconductor chip 140 may be formed together in a subsequent process (see FIG. 16). The pad conductive layer 122 may be formed to include a via portion 122V that at least partially fills the via hole and a layer portion 122L on the via portion 122V. In example embodiments, the layer portion 122L may include a plurality of metal layers. For example, the layer portion 122L may be formed by sequentially forming a copper (Cu) layer, a nickel (Ni) layer, and a gold (Au) layer. The pad conductive layer 122 may be formed, for example, by a plating process such as electrolytic plating or electroless plating.

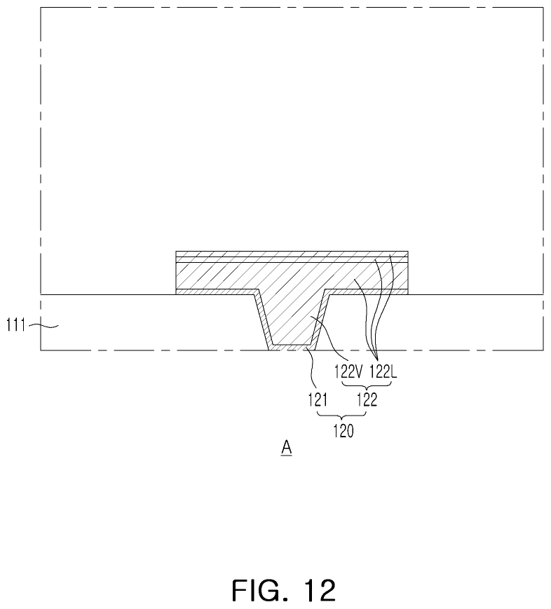

Referring to FIG. 12, the first photoresist pattern PRI may be removed and the front pad 120 may be formed. The pad seed layer 121 may be formed by removing the first photoresist pattern PR1 of the preliminary pad seed layer 121′ (see FIG. 11) and then removing the exposed portion. The portion of the preliminary pad seed layer 121′ in contact with the pad conductive layer 122 remains and may constitute the pad seed layer 121. The removal process in this operation may be, for example, an ashing or strip process. In example embodiments, after removing the first photoresist pattern PR1, a subsequent process may be performed without removing the preliminary pad seed layer 121′. In this case, an embodiment may be formed in which the pad seed layer 121 also contacts the interconnection structure 130, as illustrated in FIGS. 2 and 4.

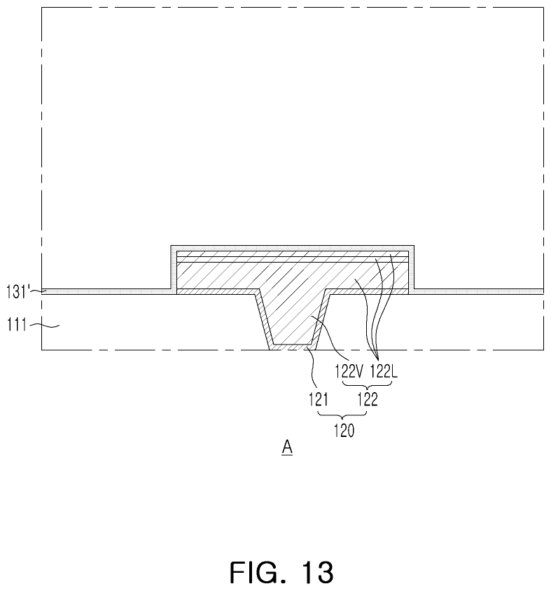

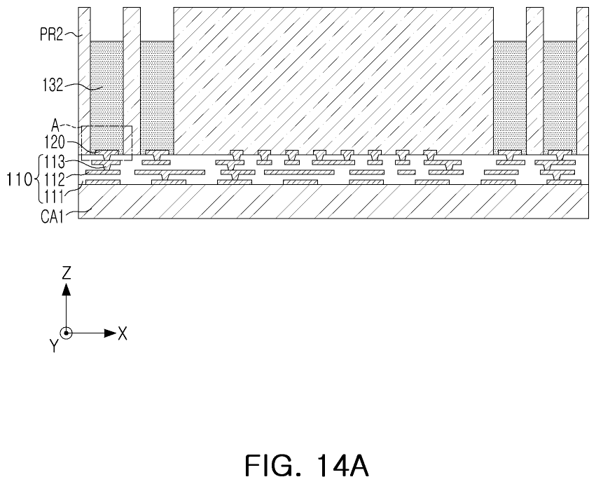

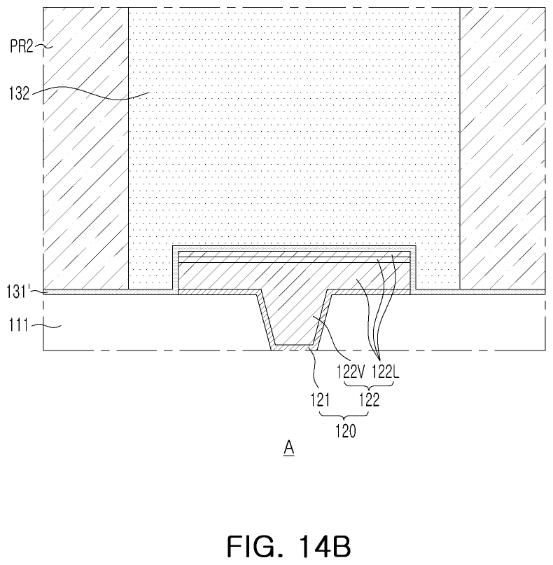

Referring to FIG. 13, a preliminary interconnection seed layer 131′ may be formed to conformally cover or overlap the upper surface of the front redistribution structure 110 and the front pad 120 in the vertical direction (e.g., Z-direction). The preliminary interconnection seed layer 131′ may cover or overlap the front redistribution layers 112 on the front insulating layer 111 in the vertical direction (e.g., Z-direction) (see FIG. 14A). The preliminary interconnection seed layer 131′ may be formed to surround the upper and side surfaces of the front pad 120. The preliminary interconnection seed layer 131′ may be formed, for example, by a deposition process such as physical vapor deposition (PVD) or chemical vapor deposition (CVD), and may include titanium (Ti) or titanium nitride (TiN). In example embodiments, this operation may be omitted. In this case, the interconnection structure 130 without a seed layer may be formed, as illustrated in FIGS. 1B, 2, and 5.

Referring to FIGS. 14A and 14B, a second photoresist pattern PR2 may be formed on the preliminary interconnection seed layer 131′, and an interconnection post 132 may be formed. The second photoresist pattern PR2 may be formed to expose the front pad 120 on the preliminary interconnection seed layer 131′. The second photoresist pattern PR2 may expose the upper surface of the front insulating layer 111 around the front pad 120. The interconnection post 132 may be formed on the preliminary interconnection seed layer 131′ exposed by the second photoresist pattern PR2. The interconnection post 132 may fill at least a portion of the portion exposed by the second photoresist pattern PR2. The interconnection posts 132 may be formed, for example, by a plating process such as electrolytic plating or electroless plating.

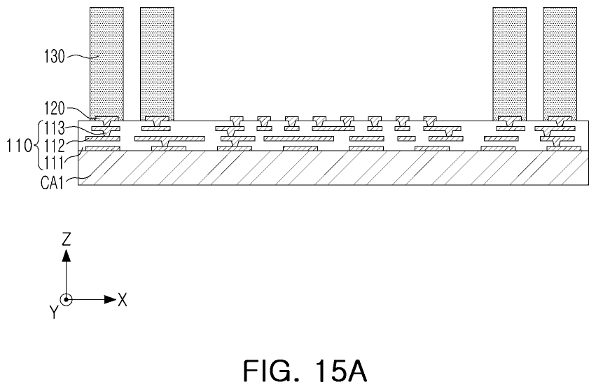

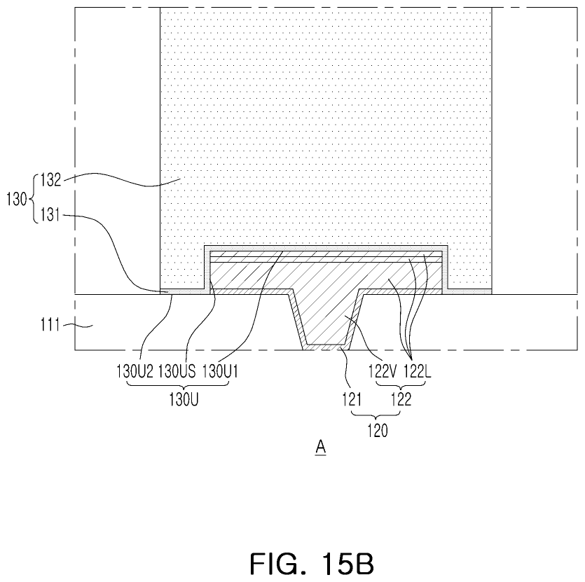

Referring to FIGS. 15A and 15B, the second photoresist pattern PR2 may be removed and the interconnection structure 130 may be formed. The interconnection seed layer 131 may be formed by removing the second photoresist pattern PR2 and then removing the exposed portion of the preliminary interconnection seed layer 131′ (see FIG. 14B). The preliminary interconnection seed layer 131′ may form the interconnection seed layer 131 with a portion remaining in contact with the interconnection post 132. The removal process in this operation may be, for example, an ashing or strip process.

Referring to FIG. 16, a semiconductor chip 140 may be mounted on the front redistribution structure 110. The semiconductor chip 140 may be mounted using a flip-chip method. For example, the semiconductor chip 140 may be connected to the front redistribution layers 112 through the connection pillar 141 and the connection solder 142 formed on the connection terminal 140P. An underfill layer 145 may be formed between the semiconductor chip 140 and the front redistribution structure 110. The underfill layer 145 may be formed using a CUF process, but is not limited thereto.

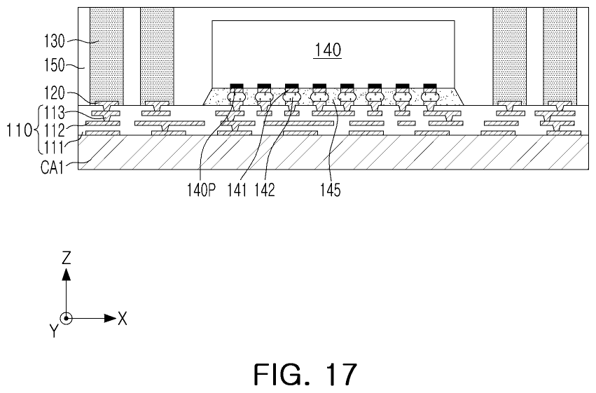

Referring to FIG. 17, an encapsulant 150 may be formed on or to seal at least a portion of each of the interconnection structure 130 and the semiconductor chip 140. The encapsulant 150 may be formed, for example, by applying and curing EMC. After the upper surface of the encapsulant 150 is formed at a higher level than the upper surface of the interconnection structure 130, portions of the interconnection structure 130 and the encapsulant 150 may be etched by the planarization process, and thus, the upper surface of the interconnection structure 130 may be exposed to the upper surface of the encapsulant 150. Therefore, as illustrated, the upper surface of the interconnection structure 130 and the upper surface of the encapsulant 150 may be coplanar. Depending on example embodiments, the upper surface of the semiconductor chip 140 may be exposed during the planarization process.

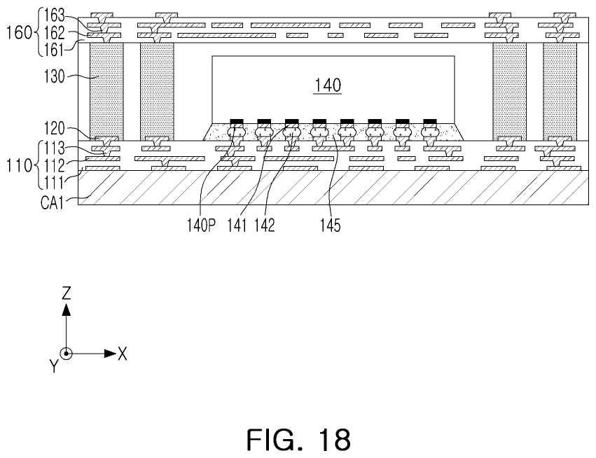

Referring to FIG. 18, a rear redistribution structure 160 may be formed that covers the upper surface of the encapsulant 150 and the upper surface of the interconnection structure 130. The rear redistribution structure 160 may be formed by a similar process as the front redistribution structure 110. The rear insulating layer 161 may be formed by sequentially applying and curing a photoimageable dielectric material, for example, PID. The rear redistribution layers 162 and the rear redistribution vias 163 may be formed by performing an exposure process and a development process to form a via hole penetrating the rear insulating layer 161, and by patterning a metal material on the rear insulating layer 161 using a plating process.

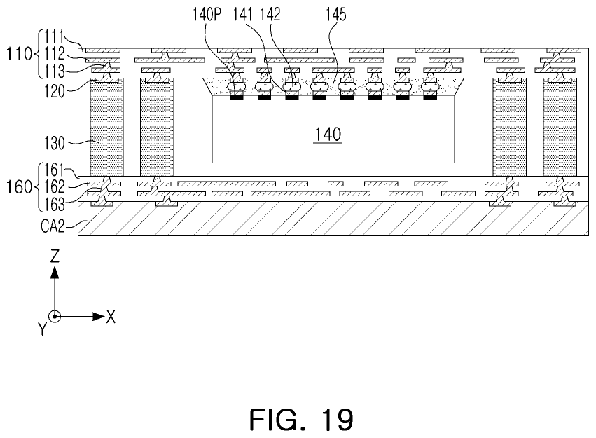

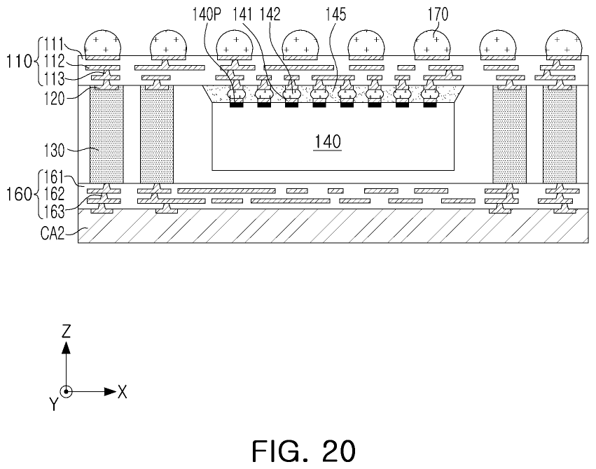

Referring to FIG. 19, a second carrier CA2 is formed on the rear redistribution structure 160, and the package may be turned over to proceed with the subsequent process. In FIGS. 19 and 20, for convenience of description, the semiconductor package illustrated in FIG. 18 is illustrated rotated or inverted in the form of a mirror image. The second carrier CA2 may include a bonding material in a portion that contacts the rear redistribution structure 160, and the rear redistribution layers 162 on the rear insulating layer 161 may be buried in the bonding material of the second carrier CA2. The second carrier CA may be removed to expose the upper surface of the front redistribution structure 110 (see FIG. 19), and one surface of the front redistribution layers 112 located on an uppermost portion (based on FIG. 19) may be exposed.

Referring to FIG. 20, external connection bumps 170 may be formed to be in contact with the exposed front redistribution layers 112. After forming the external connection bumps 170, the package may be turned over again to proceed with the subsequent process. Thereafter, referring to FIG. 1A, the second carrier CA2 may be removed. Depending on example embodiments, a subsequent process to form the upper package 200 of FIG. 7 may be performed.

As set forth above, according to example embodiments, a semiconductor package having improved electrical characteristics and reliability may be provided by forming an interconnection structure to cover at least a portion of upper and side surfaces of a front pad.

While example embodiments have been illustrated and described above, it will be apparent to those skilled in the art that modifications and variations could be made without departing from the scope of the present disclosure as defined by the appended claims.

What is claimed is:

1. A semiconductor package comprising:
a front redistribution structure that comprises a front insulating layer, front redistribution layers in the front insulating layer, and a front pad on the front insulating layer;
external connection bumps that are on a first surface of the front redistribution structure and electrically connected to the front redistribution layers;
a semiconductor chip on a second surface of the front redistribution structure that is opposite to the first surface of the front redistribution structure;
an encapsulant that is on the front redistribution structure and on a portion of the semiconductor chip;
a rear redistribution structure that comprises a rear insulating layer on the encapsulant and rear redistribution layers in the rear insulating layer; and
an interconnection structure that extends into the encapsulant and is electrically connecting the front pad and the rear redistribution layers,
wherein the interconnection structure overlaps at least a portion of an upper surface of the front pad in a first direction that is perpendicular to the first surface of the front redistribution structure and overlaps at least a portion of a side surface of the front pad in a second direction that is parallel to the first surface of the front redistribution structure.

2. The semiconductor package of claim 1, wherein a width of the front pad in the second direction is less than a width of the interconnection structure in the second direction.

3. The semiconductor package of claim 1, wherein the interconnection structure overlaps an entirety of the upper surface of the front pad in the first direction.

4. The semiconductor package of claim 3, wherein the interconnection structure at least partially surrounds the side surface of the front pad in the second direction.

5. The semiconductor package of claim 1, wherein the interconnection structure is in contact with the front insulating layer.

6. The semiconductor package of claim 1, wherein the front pad comprises a pad seed layer that at least partially overlaps the front insulating layer in the first direction and a pad conductive layer on the pad seed layer.

7. The semiconductor package of claim 6, wherein:
a first portion of an upper surface of the pad seed layer is in contact with the pad conductive layer, and
a second portion of the upper surface of the pad seed layer is in contact with the interconnection structure.

8. The semiconductor package of claim 6, wherein the pad conductive layer comprises a layer portion on the front insulating layer and a via portion that extends from a lower surface of the layer portion into the front insulating layer.

9. The semiconductor package of claim 6, wherein:
the pad seed layer comprises at least one of titanium (Ti) or titanium nitride (TiN), and
the pad conductive layer comprises at least one of copper (Cu), nickel (Ni), or gold (Au).

10. The semiconductor package of claim 1, wherein the interconnection structure comprises an interconnection seed layer that at least partially overlaps the front pad and the front insulating layer in the first direction and an interconnection post on the interconnection seed layer.

11. The semiconductor package of claim 10, wherein:
the interconnection seed layer comprises at least one of titanium (Ti) or titanium nitride (TiN), and
the interconnection post comprises at least one of copper (Cu), nickel (Ni), gold (Au), aluminum (Al), or tin (Sn).

12. The semiconductor package of claim 1, further comprising an upper package on the rear redistribution structure, wherein the upper package comprises:
an upper package substrate;
an upper semiconductor chip on a first surface of the upper package substrate;
an upper encapsulant on the upper package substrate and at least a portion of the upper semiconductor chip; and
upper connection bumps on a second surface of the upper package substrate that is opposite to the first surface of the upper package substrate, wherein the upper connection bumps are electrically connected to the rear redistribution layers.

13. A semiconductor package comprising:
a front redistribution structure that comprises a front insulating layer and front redistribution layers in the front insulating layer;
a semiconductor chip that is on the front redistribution structure and is electrically connected to the front redistribution layers;
a front pad that is spaced apart from the semiconductor chip in a first direction that is parallel to a lower surface of the front redistribution structure, is on the front redistribution structure, and is electrically connected to the front redistribution layers; and
an interconnection structure on the front pad, wherein a lower surface of the interconnection structure comprises:
a first lower surface portion in contact with an upper surface of the front pad;
a second lower surface portion having a level relative to the lower surface of the front redistribution structure that is lower than a level of the first lower surface portion relative to the lower surface of the front redistribution structure; and
an inner side surface connecting the first lower surface portion and the second lower surface portion.

14. The semiconductor package of claim 13, wherein:
the first lower surface portion overlaps an entirety of the upper surface of the front pad in a second direction that is perpendicular to the lower surface of the front redistribution structure, and
the second lower surface portion at least partially surrounds the front pad in the first direction.

15. The semiconductor package of claim 13, wherein the inner side surface of the lower surface of the interconnection structure is in contact with at least a portion of a side surface of the front pad.

16. The semiconductor package of claim 13, wherein the second lower surface portion is in contact with the front insulating layer.

17. A semiconductor package comprising:
a front redistribution structure that comprises a front insulating layer, front redistribution layers in the front insulating layer, and a front pad on the front insulating layer;
a semiconductor chip on a first surface of the front redistribution structure;
external connection bumps that is on a second surface of the front redistribution structure and is electrically connected to the front redistribution layers, wherein the second surface of the front redistribution structure is opposite to the first surface of the front redistribution structure;
an encapsulant that is on the front redistribution structure and a portion of the semiconductor chip;
a rear redistribution structure that comprises a rear insulating layer on the encapsulant and rear redistribution layers in the rear insulating layer; and
an interconnection structure that extends into the encapsulant and is electrically connected to the front pad and the rear redistribution layers,
wherein the front pad is in the interconnection structure and is spaced apart from the encapsulant in a first direction that is parallel to the first surface of the front redistribution structure.

18. The semiconductor package of claim 17, wherein the interconnection structure contacts an upper surface of the front pad, a side surface of the front pad, and an upper surface of the front insulating layer.

19. The semiconductor package of claim 17, wherein a width of the interconnection structure is between 5 μm and 500 μm in the first direction.

20. The semiconductor package of claim 17, wherein a thickness of the interconnection structure is between 50 μm and 400 μm in in a second direction that is perpendicular to the first surface of the front redistribution structure.
